(19) United States
(12) Patent Application Publication
(10) Pub. No.: US 2024/0153784 A1
(43) Pub. Date: May 9, 2024

(54) METHOD OF MANUFACTURING SEMICONDUCTOR DEVICE AND SEMICONDUCTOR DEVICE CASING

(71) Applicant: RENESAS ELECTRONICS CORPORATION, Tokyo (JP)

(72) Inventor: Satoshi ISHIDA, Tokyo (JP)

(21) Appl. No.: 18/485,614

(22) Filed: Oct. 12, 2023

(30) Foreign Application Priority Data
Nov. 9, 2022 (JP) 2022-179424

(51) Int. Cl. H01L 21/52; H01L 21/683; H01L 23/31; H01L 23/495

(52) U.S. Cl. CPC H01L 21/52; H01L 21/6835; H01L 23/3107; H01L 23/49541

(57) ABSTRACT

A carrier tape includes a first area located between first and second pockets and a first long side a second area located between the first and second pockets and a second long side; and a third area located between the first pocket and the second pocket. The third area includes a fourth area located between the first pocket and the second pocket a fifth area located between a first lead accommodating portion of the first pocket and a first lead accommodating portion of the second pocket and a sixth area located between a second lead accommodating portion of the first pocket and a second lead accommodating portion of the second pocket. Further, in a step of attaching a cover tape, the carrier tape and the cover tape are thermocompression bonded to each other at each of the first, second, fifth and sixth areas without thermocompression bonding at the fourth area.

### CROSS-REFERENCE TO RELATED APPLICATIONS

The disclosure of Japanese Patent Application No. 2022-179424 filed on Nov. 9, 2022, including the specification, drawings and abstract is incorporated herein by reference in its entirety.

### BACKGROUND

The present disclosure relates to a method of manufacturing a semiconductor device and a semiconductor device packaging body.

Here, there are disclosed techniques listed below.
[Patent Document 1] Japanese Unexamined Patent Application Publication No. 2018-002211
[Patent Document 2] Japanese Unexamined Patent Application Publication No. H11-238995

As a semiconductor device packaging body, there is a tape-like package (carrier tape) capable of accommodating a plurality of semiconductor devices. For example, Patent Document 1 and Patent Document 2 disclose a method in which after a semiconductor device is accommodated in each of a plurality of pockets formed by embossing a carrier tape, a cover tape is attached to the carrier tape so as to cover the plurality of semiconductor devices.

### SUMMARY

A semiconductor device packaging body, such as the carrier tape, is a packaging body capable of transporting a large number of semiconductor devices. In addition, since the semiconductor device can be mechanically taken out from the carrier tape when picking the semiconductor device up from the carrier tape and mounting it on the mounting substrate, the work efficiency thereof can be improved.

However, it has been found that there are the following problems depending on the attachment position of the cover tape and the attachment strength of the cover tape when attaching the cover tape to the carrier tape. For example, the semiconductor device may be jumped out from the pocket, prior to the timing that the semiconductor device is taken out from the pocket. Alternatively, if the adhesive strength between the cover tape and the carrier tape is too strong, peeling of the cover tape and the carrier tape may fail.

Other objects and novel features will become apparent from the description of this specification and the accompanying drawings.

A method of manufacturing a semiconductor device according to one embodiment, includes: a step of accommodating a plurality of semiconductor devices in a plurality of pockets, respectively of a carrier tape; and a step of attaching a cover tape to the carrier tape so as to cover the plurality of semiconductor devices respectively accommodated in the plurality of pockets. Here, the carrier tape includes: a first long side extending in a first direction; a second long side extending in the first direction and located on an opposite side of the first long side; a first area located between the plurality of pockets and the first long side; a second area located between the plurality of pockets and the second long side; and a third area located between a first pocket of the plurality of pockets and a second pocket of the plurality of pockets. The first pocket and the second pocket are adjacent to each other. Also, the third area includes: a fourth area located between a sealing body accommodating portion of a first pocket of the plurality of pockets and a sealing body accommodating portion of a second pocket of the plurality of pockets. The first pocket and the second pocket are adjacent to each other; a fifth area located between a first lead accommodating portion of the first pocket and a first lead accommodating portion of the second pocket; and a sixth area located between a second lead accommodating portion of the first pocket and a second lead accommodating portion of the second pocket. Further, in the step of attaching a cover tape to the carrier tape, the carrier tape and the cover tape are thermocompression bonded to each other at each of the first area, the second area, the fifth area and the sixth area without thermocompression bonding to each other at the fourth area.

A semiconductor device packaging body according to another embodiment, includes: a carrier tape having a plurality of pockets arranged in a first direction; a plurality of semiconductor devices accommodated in the plurality of pockets, respectively; and a cover tape attached to the carrier tape so as to cover the plurality of semiconductor devices respectively accommodated in the plurality of pockets. Here, the carrier tape includes: a first long side extending in the first direction; a second long side extending in the first direction and located on an opposite side of the first long side; a first area located between the plurality of pockets and the first long side; a second area located between the plurality of pockets and the second long side; and a third area located between a first pocket of the plurality of pockets and a second pocket of the plurality of pockets. The first pocket and the second pocket are adjacent to each other. Also, the third area includes: a fourth area located between a sealing body accommodating portion of the first pocket and a sealing body accommodating portion of the second pocket; a fifth area located between a first lead accommodating portion of the first pocket and a first lead accommodating portion of the second pocket; and a sixth area located between a second lead accommodating portion of the first pocket and a second lead accommodating portion of the second pocket. Further, each of the first area, the second area, the fifth area and the sixth area has a seal portion at where the carrier tape and the cover tape are thermocompression bonded to each other, while the fourth area has no seal portion at where the carrier tape and the cover tape are thermocompression bonded to each other.

According to the one embodiment, it is possible to improve the performance of the semiconductor device packaging body.

### BRIEF DESCRIPTION OF THE DRAWINGS

FIG. 1 is an explanatory diagram showing an example of a process flow of a method of manufacturing a semiconductor device according to an embodiment.

FIG. 2 is an upper surface view of the semiconductor device according to the embodiment.

FIG. 3 is a cross-sectional view along an A-A line in FIG. 2.

FIG. 4 is an enlarged plan view of a carrier tape according to the embodiment.

FIG. 5 is an enlarged cross-sectional view along a B-B line in FIG. 4.

FIG. 6 is an enlarged plan view showing a situation in which one semiconductor device is accommodated in each of a plurality of pockets of the carrier tape shown in FIG. 4.

FIG. 7 is an enlarged cross-sectional view along a C-C line in FIG. 6.

FIG. 8 is an enlarged plan view showing a situation in which the one semiconductor device is accommodated in each of the plurality of pockets of the carrier tape shown in FIG. 4.

FIG. 9 is an enlarged cross-sectional view along a D-D line in FIG. 8.

FIG. 10 is an enlarged plan view showing a first examined example with respect to FIG. 8.

FIG. 11 is a cross-sectional view at an E-E line in FIG. 10, which is showing a situation in which a semiconductor device is jumped out from the pocket.

FIG. 12 is an enlarged plan view showing a second examined example with respect to FIG. 8.

FIG. 13 is an enlarged plan view showing a periphery of a region between two pockets, which are adjacent to each other, of the plurality of pockets in a carrier tape package shown in FIG. 8.

FIG. 14 is an enlarged plan view showing a modified example with respect to FIG. 13.

FIG. 15 is an enlarged plan view showing a modified example with respect to FIG. 14.

FIG. 16 is an enlarged plan view showing another modified example with respect to FIG. 13.

FIG. 17 is an enlarged plan view showing another modified example with respect to FIG. 13.

### DETAILED DESCRIPTION

(Description of Forms, Basic Terms and Usage in Present Application)

In the present application, the description of the embodiment will be divided into a plurality of sections or the like as required for convenience, but unless expressly stated otherwise, these are not independent of each other, and each part of a single example, one of which is a partial detail or a part or all of the other, whether before or after the description, or the like, is modified example or the like. In principle, descriptions of similar parts are omitted. Also, each component in an embodiment is not essential, unless expressly stated otherwise, theoretically limited to that number, and obviously otherwise from the context.

Similarly, in the description of the embodiment and the like, “X consisting of A” or the like with respect to the material, composition, and the like does not exclude elements other than A, except when it is clearly indicated that this is not the case and when it is obvious from the context that this is not the case. For example, regarding a component, it means “X including A as a main component” or the like. For example, the term “silicon member” or the like is not limited to pure silicon, and it is needless to say that it also includes a member containing a SiGe (Silicon Germanium) alloy, a multi-element alloy containing silicon as its main component, other additives, or the like. In addition, gold plating, Cu layers, nickel plating, and the like, unless otherwise specified, not only pure, but also gold, Cu, nickel, and the like as the main constituent members, respectively, shall be included.

In addition, the reference to a specific numerical value or quantity may be greater than or less than that specific numerical value, unless expressly stated otherwise, theoretically limited to that number, and obviously not so from the context.

In the drawings of the embodiments, the same or similar parts are denoted by the same or similar symbols or reference numerals, and the description will not be repeated in principle.

In addition, in the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. In addition hatching or dot patterns may be added to indicate that the region is not a void even if it is not a cross-section or to indicate the boundary of the area.

In the embodiment described below, as a method of attaching a carrier tape and a cover tape with each other, a method of thermocompression bonding by pressing a heat pressing jig from an upper portion in a state in which a part of the carrier tape and a part of the cover tape are in contact with each other is employed. Hereinafter, the thermocompression bonding is referred to as a seal, and the thermocompression bonded portion is sometimes referred to as a seal portion. Further, the heating and pressing jig is sometimes referred to as a trowel. Further, the property of the adhesive state after the thermocompression bonding is referred to as a seal property, and the property when the thermocompression bonded portion is peeled off is sometimes referred to as a peel property.

<Method of Manufacturing Semiconductor Device>

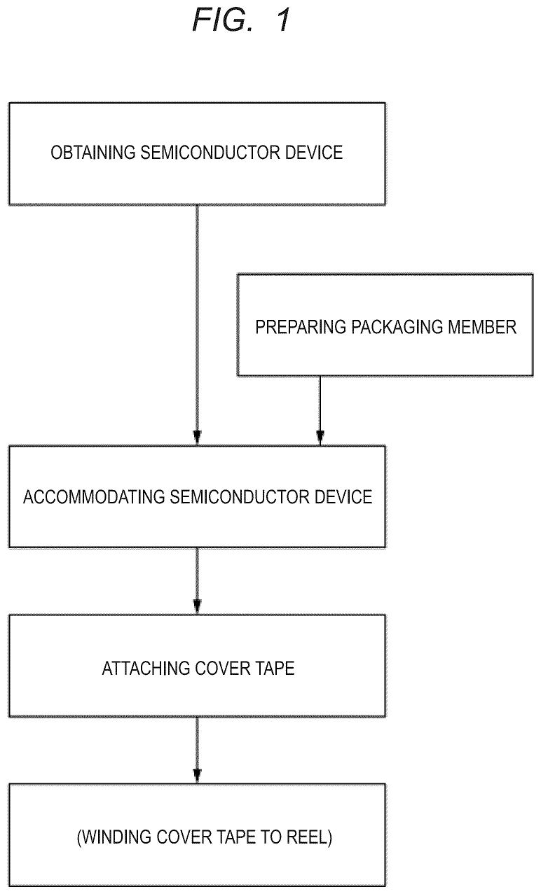

First, with regard to a method of manufacturing a semiconductor device according to the present embodiment, until the semiconductor device is accommodated in the carrier tape and packaged (namely, a method of packaging the semiconductor device) will be briefly described. FIG. 1 is an explanatory diagram showing an example of a process flow of the method of manufacturing the semiconductor device according to the present embodiment.

The method of manufacturing the semiconductor device according to the present embodiment includes a step of obtaining the semiconductor device, a step of preparing a packaging member, a step of accommodating the semiconductor device, a step of attaching the cover tape, and a step of winding the carrier tape to a reel. Note that the reel winding process may be omitted, and is therefore described in parentheses.

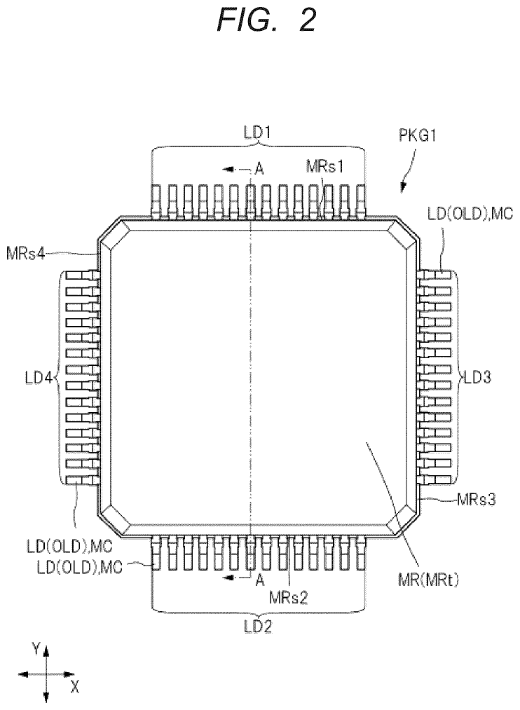

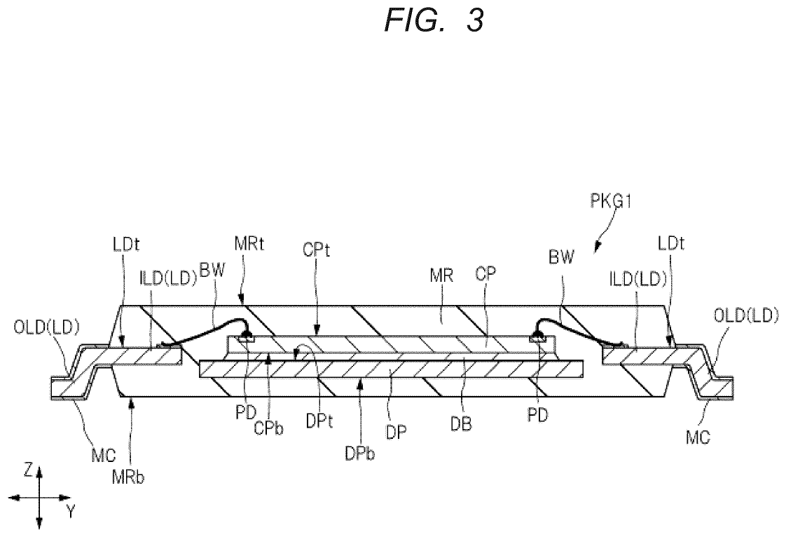

In the step of obtaining the semiconductor device, the semiconductor device (semiconductor package) PKG1, which is shown in FIGS. 2 and 3 described later, is obtained.

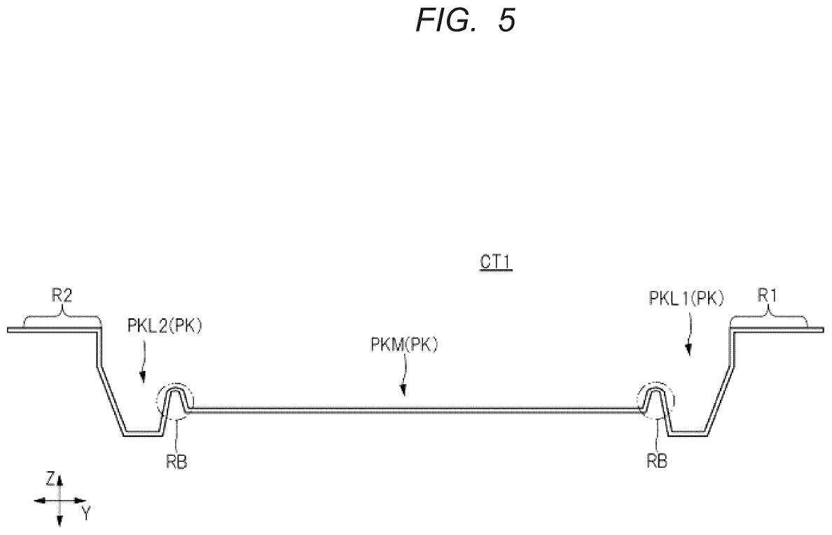

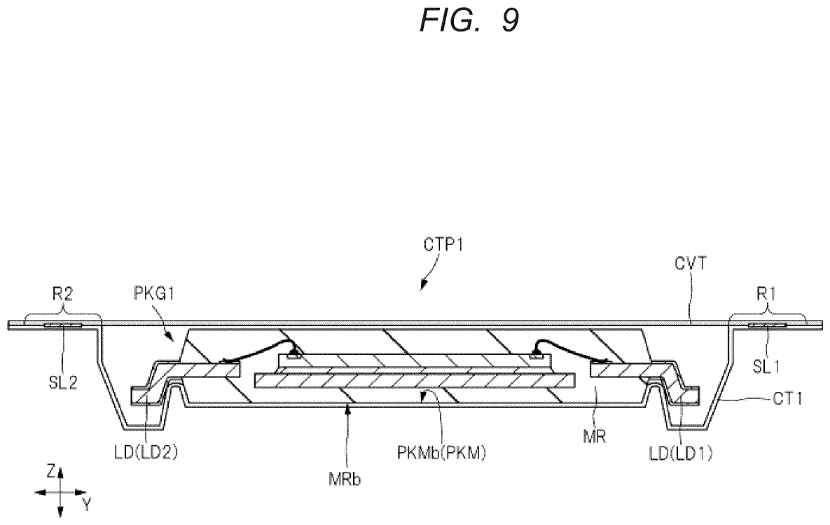

In the step of preparing the packaging member, a carrier tape package CTP1 shown in FIG. 5 to be described later and the cover tape CVT shown in FIG. 9 to be described later are prepared.

In the step of accommodating the semiconductor device, a plurality of semiconductor devices PKG1 is respectively accommodated in a plurality of pockets of the carrier tape prepared in the step of preparing the packaging member. In the step of attaching the cover tape, the cover tape is attached to the carrier tape so as to cover the plurality of semiconductor devices respectively accommodated in the plurality of pockets.

In the step of winding the carrier tape to the reel, the carrier tape in which a plurality of semiconductor devices PKG1 is accommodated and the cover tape is attached is wound onto a reel (not shown). In the present specification, the carrier tape in which a plurality of semiconductor devices PKG1 is accommodated and the cover tape is attached is described as a semiconductor device packaging body or a carrier tape package.

<Semiconductor Device Obtaining Step>

Next, an exemplary configuration of the semiconductor device obtained in the step of obtaining the semiconductor device, which is shown in FIG. 1, will be described. FIG. 2 is an upper surface view of the semiconductor device according to the present embodiment. FIG. 3 is a cross-sectional view along an A-A in FIG. 2.

The semiconductor device PKG1 includes a semiconductor chip CP (see FIG. 3), a plurality of leads LD arranged around the semiconductor chip CP, and a sealing body MR. As shown in FIG. 3, the sealing body MR seals an inner lead portion ILD of each of the plurality of leads LD and the semiconductor chip CP.

As shown in FIG. 3, the semiconductor chip CP is mounted on a die pad (chip mounting portion) DP (see FIG. 3). The die pad DP has an upper surface (chip mounting surface) DPt facing the semiconductor chip CP, and a lower surface (rear surface) DPb opposite the upper surface DPt. The semiconductor device PKG1 further includes a plurality of wires BW electrically connecting a plurality of pads PD of the semiconductor chip CP with the plurality of leads LD, respectively, at the inner lead portion ILD. The plurality of wires BW and the die pad DP are sealed with the sealing body MR. In an example shown in FIG. 3, the entire die pad DP is sealed with the sealing body MR. However, as a modified example, the lower surface DPb of the die pad DP may be exposed from the sealing body.

The sealing body MR is a resin body containing a resin material as a main component, and contains, for example, filler particles such as silica and a black pigment. As shown in FIG. 2, the sealing body MR of the semiconductor device PKG1 has a rectangular planar shape. The sealing body MR has an upper surface MRt and a lower surface (rear surface, mounted surface) MRb (see FIG. 3) opposite the upper surface MRt. Further, as shown in FIG. 2, in a plan view, the sealing body MR has a side MRs1 extending in the X-direction, a side MRs2 located on the opposite side of the side MRs1, a side MRs3 extending in the Y-direction intersecting each of the side MRs1 and the side MRs2, and a side MRs4 located on the opposite side of the side MRs3. In an example shown in FIG. 2, a corner portion where the respective side surface MRs of the sealing body MR intersect with each other is chamfered.

In the semiconductor chip CP shown in FIG. 3, a plurality of pads (bonding pads) PD is provided on a front surface CPt. Further, the semiconductor chip CP (specifically, semiconductor substrate) is made of, for example, silicon (Si). Although not shown, a plurality of semiconductor elements (circuit elements) is formed in the semiconductor chip CP (in particular, semiconductor element forming region provided on upper surface of semiconductor substrate of semiconductor chip CP) at the main surface of the semiconductor chip CP. Then, a plurality of pads PD is electrically connected with the semiconductor element through a wiring (not shown) formed in a wiring layer provided in the semiconductor chip CP (specifically, between front surface CPt and semiconductor element forming region which is not shown). The plurality of pads PD is electrically connected with a circuit formed in the semiconductor chip CP.

Further, an insulating film covering a substrate of the semiconductor chip CP and the wiring is formed on the front surface CPt of the semiconductor chip, and the surface of each of the plurality of pads PD is exposed from the insulating film in an opening portion formed in the insulating film. In addition, the pad PD is made of a metal. In the present embodiment, it is, for example, made of aluminum (Al).

The semiconductor chip CP is mounted in the central of the die pad DP. As shown in FIG. 3, the semiconductor chip CP is mounted on the die pad DP with a rear surface CPb facing upper surface DPt of the die pad DP via a bonding material (die bonding material) DB. The bonding material DB is made of a conductive resin or a solder material containing a resin body and a plurality of metallic particles contained in the resin body. Examples of the conductive resin include an adhesive member called a so-called silver paste in which metal particles made of silver or the like are contained in an epoxy-based thermosetting resin (resin body).

A plurality of leads LD is arranged around the semiconductor chip CP (in other words, around the die pad DP) (see FIGS. 2 and 3). Each of the plurality of leads LD is an external terminal having a function of electrically connecting the semiconductor device PKG1 with an external device (not shown).

In the semiconductor device PKG1, a plurality of leads LD is arranged along each side (each main side) of the sealing body MR having a rectangular planar shape. In other words, the plurality of leads LD includes a lead group LD1 arranged along the side MRs1 of the sealing body MR, a lead group LD2 arranged along the side MRs2, a lead group LD3 arranged along the side MRs3, and a fourth lead group LD4 arranged along the side MRs4. As shown in the semiconductor device PKG1, a semiconductor package in which a plurality of leads LD is arranged along each of four sides of the sealing body MR having a square shape in a plan view is referred to as a QFP (Quad Flat Package).

The inner lead portion ILD (refer to FIG. 3) of each of the plurality of leads LD is sealed to the sealing body MR, and the outer lead portion OLD of each of the plurality of leads LD is exposed from the sealing body MR. The outer lead portion OLD of each of the plurality of leads LD protrude toward the outer side of the sealing body MR on the side surface MRs of the sealing body MR. The plurality of pads (bonding pads) PD exposed on the front surface CPt of the semiconductor chip CP are electrically connected to the inner lead portions ILD of the plurality of lead LD located inside the sealing body MR via the plurality of wires (conductive members) BW.

The die pad DP and the plurality of leads LD are made of the same metallic material. An example of the metallic material composing the die pad DP and the plurality of leads LD includes copper, an alloy containing copper, or an alloy containing iron (42 alloy).

Each of the plurality of wires BW is a thin metallic wire that electrically connects a plurality of pads (bonding pads) PD (see FIG. 3) and a plurality of leads provided on the front surface CPt (see FIG. 3) of the semiconductor chip CP. One end of the wire BW is bonded to the pad PD, and the other end is bonded to the lead LD via a metallic film formed on upper surface LDt of the lead LD (see FIG. 3). Each of the plurality of wires BW is sealed by a sealing member MR. Thus, deformation or the like of the wire BW can be prevented.

The wire BW is made of, for example, gold (Au) or copper (Cu), a part of the wire BW (e.g., one end) is bonded to the pad PD, and the other part (e.g., the other end) is bonded to the distal end of the inner lead portion ILD. In the embodiment shown in FIG. 3, the wire BW is connected to the inner lead portion ILD via a metallic film formed at the distal end portion of the inner lead portion ILD.

As shown in FIG. 3, a metal film (exterior plating film) MC is formed on the exposed surface of the outer lead portion OLD of the plurality of leads LD, for example, on the surface of the base material. Further, the lower surface DPb of the die pad DP is exposed from the sealing body MR.

The metal film MC is, for example, a metal film made of a metal material having better wettability to solder than copper as a base material, such as solder, and covering the surface of the copper member as a base material.

<Packaging Member Preparing Step>

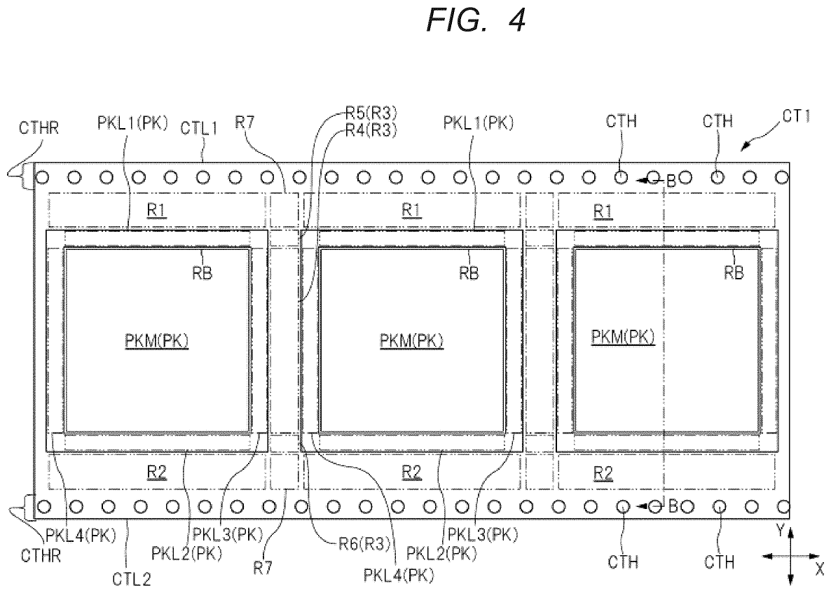

Next, an example of the structure of the carrier tape prepared in the step of preparing the packaging member, which is shown in FIG. 1, will be described. FIG. 4 is an enlarged plan view of the carrier tape according to the present embodiment. FIG. 5 is an enlarged cross-sectional view along a B-B line in FIG. 4.

The carrier tape CT1 is a resin tape made of a resin material such as a thermoplastic resin (for example, a polystyrene based resin). The film thickness of the carrier tape is, for example, about 0.3 mm. As shown in FIG. 4, the carrier tape CT1 has a plurality of pockets PK formed by embossing. The carrier tape CT1 is an elongated tape and has a large number of pockets PK. In FIG. 4, three pockets of the plurality of pockets PK included in the carrier tape CT1 are shown in an enlarged manner.

As shown in FIG. 4, the carrier tape CT1 has a long side CTL1 extending in the X-direction and a long side CTL2 extending in the X-direction and located on the other side of the long side CTL1. Further, the carrier tape CT1 has an area R1 located between a plurality of pockets PK and the long side CTL1, an area R2 located between the plurality of pockets PK and the long side CTL2, and an area R3 located between two (first pocket, second pocket) of the plurality of pockets PK, which are adjacent to each other. Further, the carrier tape CT1 has an area R7 located between a plurality of areas R1 arranged in the X-direction, and an area R8 located between a plurality of areas R2 arranged in the X-direction.

The area R7 and the area R8 can be expressed as follows. That is, the area R7 is arranged in the X-direction, is located next to the area R1, and is located next to the area R5 in the Y-direction intersecting the X-direction. The area R8 is arranged in the X-direction, is located next to the area R2, and is located next to the area R6 in the Y-direction intersecting the X-direction.

Between the long side CTL1 and the area R1, a hole arrangement region CTHR in which a plurality of through holes CTH are arranged in the X-direction is arranged. The plurality of through holes CHT are arranged at equal intervals. The plurality of through holes CTH are sprocket holes for inserting teeth of a sprocket (not shown) when the carrier tape CT1 is moved in device. In the embodiment shown in FIG. 4, the hole arrangement region CTHR in which a plurality of through holes CTH are arranged is provided between the long side CTL1 and the area R1 and between the long side CTL2 and the area R2. However, as a modified example to the embodiment shown in FIG. 4, the hole arrangement region CTHR may be arranged only in one of the long side CTL1 and the area R1 and the long side CTL2 and the area R2.

Each of the plurality of pockets PK includes a sealing body accommodating portion PKM, a lead accommodating portion PKL1, a lead accommodating portion PKL2, a lead accommodating portion PKL3, and a lead accommodating portion PKL4. The sealing body accommodating portion PKM is a portion for accommodating the sealing body MR of the semiconductor device shown in FIG. 2, and is disposed in a central portion (an area including the center) of the pocket PK in a plan view.

The lead accommodating portion PKL1 extends along the long side CTL1. The lead accommodating portion PKL1 is a portion for accommodating the lead group LD1 shown in FIG. 2, and is disposed between the long side CTL1 and the sealing body accommodating portion PKM.

The lead accommodating portion PKL2 extends along the long side CTL2. The lead accommodating portion PKL2 is a portion for accommodating the lead group LD2 shown in FIG. 2, and is disposed between the long side CTL2 and the sealing body accommodating portion PKM.

The lead accommodating portion PKL3 extends in the extending direction (Y-direction) of an area R3. The lead accommodating portion PKL3 is a portion for accommodating the lead group LD3 shown in FIG. 2, and is disposed between the area R3 and the sealing body accommodating portion PKM.

The lead accommodating portion PKL4 extends in the extending direction (Y-direction) of the area R3. The lead accommodating portion PKL4 is a portion for accommodating the lead group LD4 shown in FIG. 2, and is disposed between the area R3 and the sealing body accommodating portion PKM.

As shown in FIG. 5, a rib RB is provided between the sealing body accommodating portion PKM and the lead accommodating portion PKL1 and between the sealing body accommodating portion PKM and the lead accommodating portion PKL2, and the accommodating portions are separated via ribs. Similarly, a rib RB is also provided between the sealing body accommodating portion PKM and the lead accommodating portion PKL3 shown in FIG. 4 and between the sealing body accommodating portion PKM and the lead accommodating portion PKL4. The ribbing RB is a portion formed so as to have a frame shape in a plan view. When semiconductor device PKG1 shown in FIG. 3 is accommodated in the pocket PK by providing the rib RB around the sealing body accommodating portion PKM, the position of the sealing body MR can be controlled with high accuracy. The ribbed RB is formed, for example, together with the pocketed PK when the carrier tape CT1 is embossed.

Further, in the embodiment shown in FIG. 4, the area R3 includes an area R4 located between two of the plurality of sealing body accommodating portions PKM, which are adjacent to each other, an area R5 located between two of the lead accommodating portions PKL1, which are adjacent to each other, and an area R6 located between two of the lead accommodating portions PKL2, which are adjacent to each other.

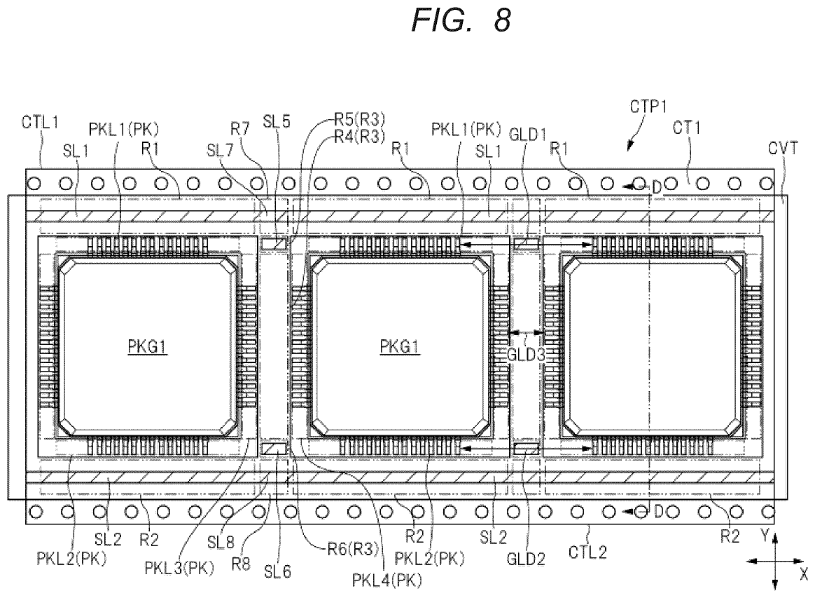

Further, the cover tape CVT (see FIG. 8 to be described later) used in the step of attaching the cover tape, which is shown in FIG. 1, may be prepared until the step of attaching the cover tape, but it is preferable that the cover tape CVT is prepared at the time of the step of preparing the packaging member (i.e., prior to the step of accommodating the semiconductor device) when the step of accommodating the semiconductor device and the step of attaching the cover tape, which are shown in FIG. 1, are continuously performed using the consecutive treatment device. The cover tape CVT is an elongated tape formed in a band shape. The cover tape CVT is a resin tape made of resin. From the viewpoint of improving visibility in the pocket PK (see FIG. 4), the cover tape CVT is preferably a visible light transmissive resin. The material of the cover tape CVT, in the step of attaching the cover tape shown in FIG. 1, the appropriate material is selected in consideration of the adhesive strength (the difficulty of peeling, namely, the seal property at the time of conveyance, and the peel property at the time of peeling) to the carrier tape CT1 (refer to FIG. 4).

<Semiconductor Device Accommodating Step>

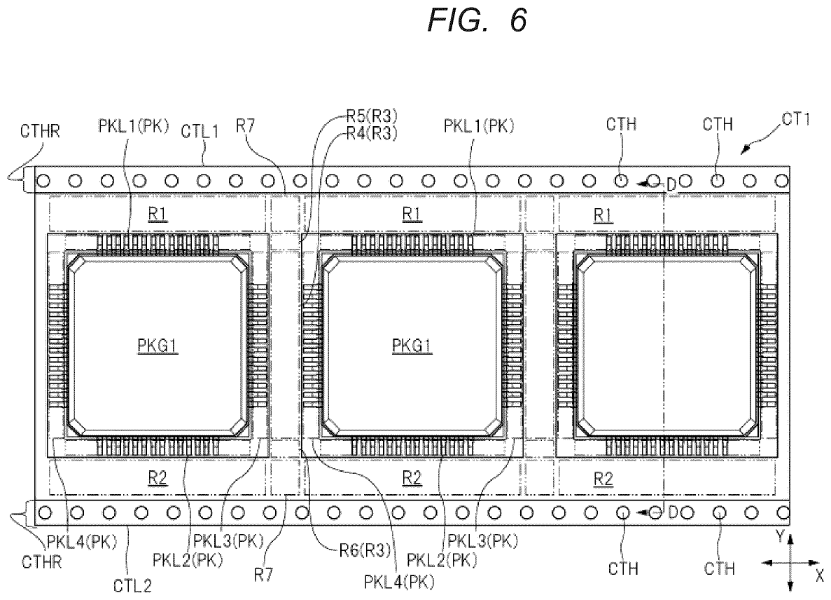

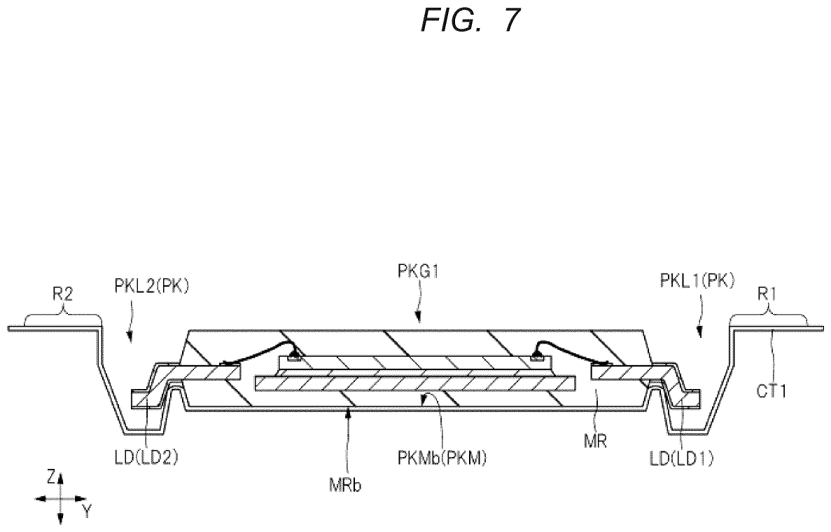

Next, the step of accommodating the semiconductor device, which is shown in FIG. 1, will be described. FIG. 6 is an enlarged plan view showing a situation in which one semiconductor device is accommodated in each of the plurality of pockets of the carrier tape shown in FIG. 4. FIG. 7 is an enlarged cross-sectional view along a C-C line in FIG. 6.

As shown in FIG. 6, in the step of accommodating the semiconductor device, one semiconductor device PKG1 is accommodated in each of the plurality of pockets PK of the carrier tape CT1. Note that “accommodating one semiconductor device PKG1 one by one” means “accommodating one semiconductor device PKG1 in one pocket PK”. Of course, this step also includes an embodiment in which the semiconductor device PKG1 is accommodated in the pocket PK one by one, but also an embodiment in which, for example, two semiconductor devices PKG1 are respectively and simultaneously accommodated in two pockets PK.

Since the position of the pocket PK is positioned using the plurality of through holes CTH, the pick up device (not shown) can be used to automatically accommodate semiconductor device PKG1 in the pocket PK. The rib RB (see FIG. 5) serves as a guide for controlling the position of semiconductor device PKG1 in the pocket PK, in particular the position of the sealing body MR. For this reason, the sealing body MR (see FIG. 7) of semiconductor device PKG1 is accommodated in the sealing body accommodating portion PKM (see FIGS. 4 and 5) of the pocketed PK.

Further, the lead group LD1 shown in FIG. 3 is accommodated in the lead accommodating portion PKL1 shown in FIG. 6, the lead group LD2 shown in FIG. 3 is accommodated in the lead accommodating portion PKL2 shown in FIG. 6, the lead group LD3 shown in FIG. 3 is accommodated in the lead accommodating portion PKL3 shown in FIG. 6, and the lead group LD4 shown in FIG. 3 is accommodated in the lead accommodating portion PKL4 shown in FIG. 6. In the embodiment shown in FIG. 7, after the completion of this step, the lower surface MRb of the sealing body MR contacts the bottom surface PKMb of the sealing body accommodating portion PKM (see FIG. 5) of the carrier tape CT1.

<Cover Tape Attaching Step>

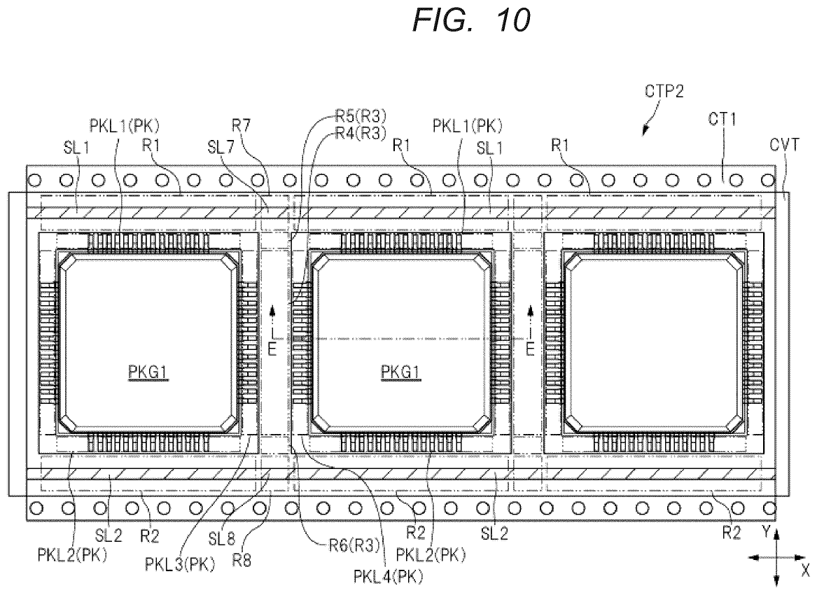

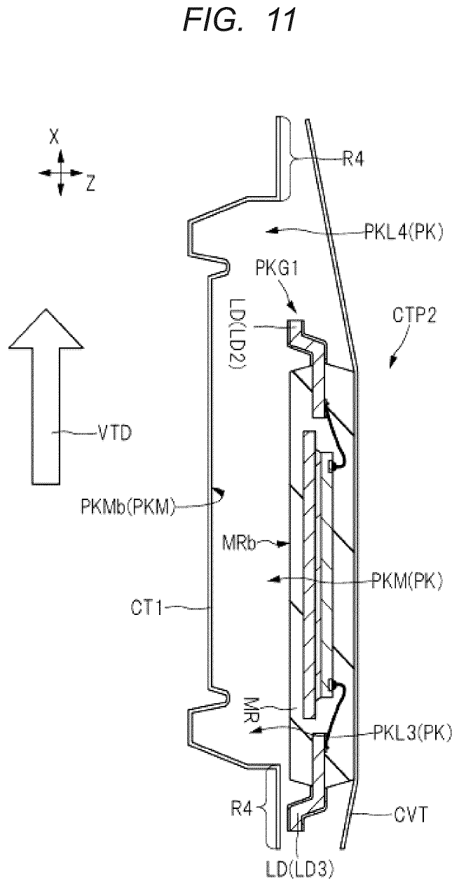

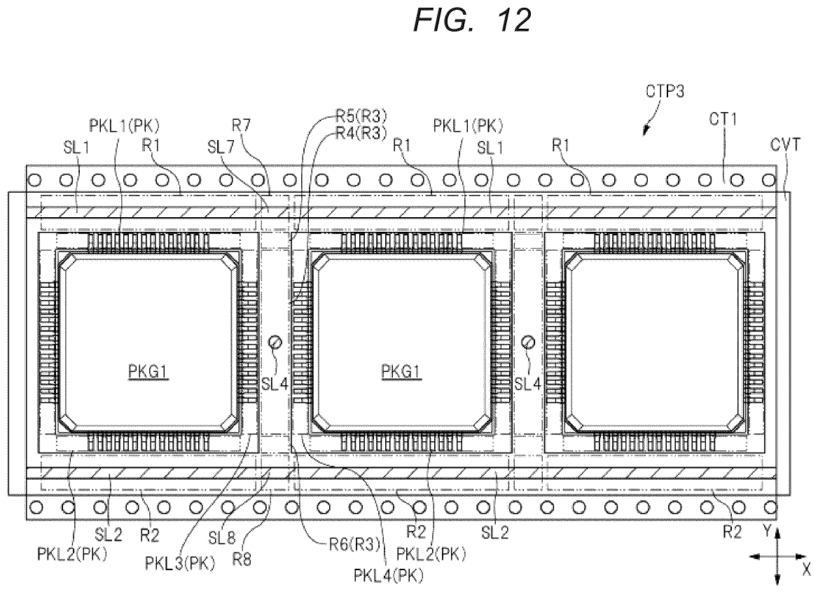

Next, the step of attaching the cover tape shown in FIG. 1 will be described. FIG. 8 is an enlarged plan view showing a situation in which the one semiconductor device is accommodated in each of the plurality of pockets of the carrier tape shown in FIG. 4. FIG. 9 is an enlarged cross-sectional view along a D-D line in FIG. 8. FIG. 10 is an enlarged plan view showing a first examined example with respect to FIG. 8. FIG. 11 is a cross-sectional view at an E-E line in FIG. 10, which is showing a situation in which a semiconductor device is jumped out from the pocket. FIG. 12 is an enlarged plan view showing a second examined example with respect to FIG. 8.

In the step of attaching the cover tape, a portion of the cover tape CVT and a portion of the carrier tape CT1 are thermocompression bonded to each other. For the present embodiment, as a method of bonding the carrier tape CT1 and the cover tape CVT, a method of thermocompression bonding by pressing a heat pressing jig (hereinafter referred to as an iron) from the upper part while a part of the carrier tape CT1 and a part of the cover tape CVT are in contact is employed. Hereinafter, a portion to be thermocompression bonded in the step of attaching cover tape will be described as a seal portion. Further, for example, a seal portion SL1, a seal portion SL2, a seal portion SL5, a seal portion SL6, a seal portion SL7, and a seal portion SL8 shown in FIG. 8, and the seal portion SL1 and the seal portion SL2 shown in FIG. 9, the portions to be thermocompression bonded, regardless of whether plan view or cross-sectional view, are illustrated by hatching.

The semiconductor device PKG1 is accommodated in the pocket PK by the step of accommodating the semiconductor device described by using FIGS. 6 and 7, but, in the state shown in FIG. 7, the semiconductor device PKG1 accommodated is jumped out to the outside of the pocket PK due to the attitude of the carrier tape CT1. Therefore, in the subsequent step of attaching the cover tape, the cover tape CVT (see FIG. 9) is attached to the carrier tape CT1 so as to cover the semiconductor device PKG1 as shown in FIG. 9, and thus, it is possible to prevent the semiconductor device PKG1 from jumping out to the outside of the pocket PK.

First, as shown in FIG. 10, the present inventor have studied a method of thermocompression bonding both adjacent parts of a plurality of semiconductor devices PKG1 along the X-direction. For examined example shown in FIG. 10, the carrier tape CT1 and the cover tape CVT are thermocompression bonded in the area R1, the area R2, the area R7, and the area R8. On the other hand, in the area R3, the carrier tape CT1 and the cover tape CVT are not thermocompression bonded. In the case of the structure shown in FIG. 10, the structure of the soldering iron for thermocompression bonding can be simplified. In addition, the seal portion SL1, the seal portion SL7, the seal portion SL2, and the seal portion SL8 extend in the X-direction with the same width. For this reason, there is little concern about misalignment or the like of the thermocompression-bonded portion.

However, according to studies by the present inventor, it has been found that, in case of the structure of FIG. 10 in which the area between two adjacent semiconductor devices PKG1 is not bonded, the accommodated semiconductor device PKG1 may be jumped out from the pocketed PK as shown in FIG. 11. FIG. 11 shows a state where a carrier tape package CTP2 is pulled up toward the vertically upward VTD when the carrier tape package CTP2 accommodating semiconductor device PKG1 is unwound from a reel (not shown).

As shown in FIG. 11, if a portion of semiconductor device PKG1 pops out of the pocket PK, it is difficult to automatically return into the pocket PK. For this reason, it is required to shut down device and manually move semiconductor device PKG1 back into the pocketing PK. If semiconductor device PKG1 pops out of the pocketed PK frequently, device will be stopped frequently, resulting in a decrease in operating efficiencies.

Therefore, in order to prevent the phenomena as shown in FIG. 11, as in a carrier tape package CTP3 shown as another examined example in FIG. 12, the carrier tape CT1 and the cover tape CVT are thermocompression bonded to a part of the area R4 to study a structure including a seal portion SL4. In the carrier tape package CTP3, since a part of the area R4 is thermocompression bonded, it is possible to prevent semiconductor device PKG1 from being jumped out from the pocket PK as in the carrier tape package CTP2 shown in FIG. 11.

However, in the carrier tape package CTP3, it is difficult to align the seal portion SL4. The step of accommodating the semiconductor device and the step of attaching the cover tape, which are shown in FIG. 1, are performed continuously using an automated device. Therefore, it is difficult to align the carrier tape CT1 in the extending direction (X-direction shown in FIG. 12) as compared with the alignment in the widthwise direction (Y-direction shown in FIG. 12) of the carrier tape CT1. When the position of the seal portion SL4 is shifted in the X-direction, there are cases where the lead group LD3 of semiconductor device PKG1 (refer to FIG. 2), the lead group LD4 (see FIG. 2), or the soldering iron for thermocompression bonding contacts the sealing body MR via the cover tape CVT. The lead LD (see FIG. 2) or the sealing body MR may be damaged by the contact of the trowel.

In order to prevent the semiconductor device PKG1 from being damaged, it is also conceivable to increase the width (length in the X-direction) of the area R4 in order to increase the margin of the positional deviation in the area R4. However, the number of semiconductor devices PKG1 that can be accommodated per unit area (in other words, unit length in the X-direction) of the carrier tape CT1 is reduced.

Here, in case of the method of manufacturing the semiconductor device according to the present embodiment shown in FIGS. 8 and 9, as shown in FIG. 8, in the step of attaching the cover tape, the carrier tape CT1 and the cover tape CVT are thermocompression bonded to each other at each of the area R1, the area R2, the area R5 and the area R6, but the carrier tape and the cover tape CVT are not thermocompression bonded to each other at the area R4. In other words, in case of the carrier tape package (semiconductor device packaging body) CTP1 obtained in the present embodiment, the seal portion SL1 is provided (situated) in the area R1, the seal portion SL2 is provided (situated) in the area R2, the seal portion SL5 is provided (situated) in the area R5, and the seal portion SL6 is provided (situated) in the area R6, but the seal portion is not provided (situated) in the area R4.

The carrier tape package CTP1 according to the present embodiment, the carrier tape CT1 and the cover tape CVT are thermocompression bonded to each other in the area R5 and the area R6 included in the area R3 disposed between two adjacent pocket PK. Therefore, as compared with the carrier tape package CTP2 shown in FIG. 10, it is possible to prevent semiconductor device PKG1 from being jumped out from the pocket PK. In the carrier tape package CTP1 shown in FIG. 8, the seal portion is provided in the area R5 and the area R6. The separation distance GLD1 between two lead groups LD1 (refer to FIG. 2) adjacent to each other via the area R5 and the separation distance GLD2 between two lead groups LD2 (see FIG. 2) adjacent to each other via the area R6 are the same in designing. Further, each of the separation distance GLD1 and the separation distance GLD2 is larger than the separation distance GLD3 between the adjacent lead group LD3 (refer to FIG. 2) and the lead group LD4 (see FIG. 2) via the area R4. Therefore, in the carrier tape package CTP1 shown in FIG. 8, even when the positions of the seal portion SL5 and the seal portion SL6 are displaced in the X-direction, the soldering iron for thermocompression bonding hardly contacts semiconductor device PKG1.

Further, the carrier tape package CTP1 according to the present embodiment, it is possible to prevent semiconductor device PKG1 from being damaged without increasing the width of the area R3 in the X-direction in preparation for the positional deviation between the seal portion SL5 and the seal portion SL6. Therefore, the number of semiconductor device PKG1 that can be accommodated per terminal area (in other words, the length in the X-direction) of the carrier tape CT1 is not reduced.

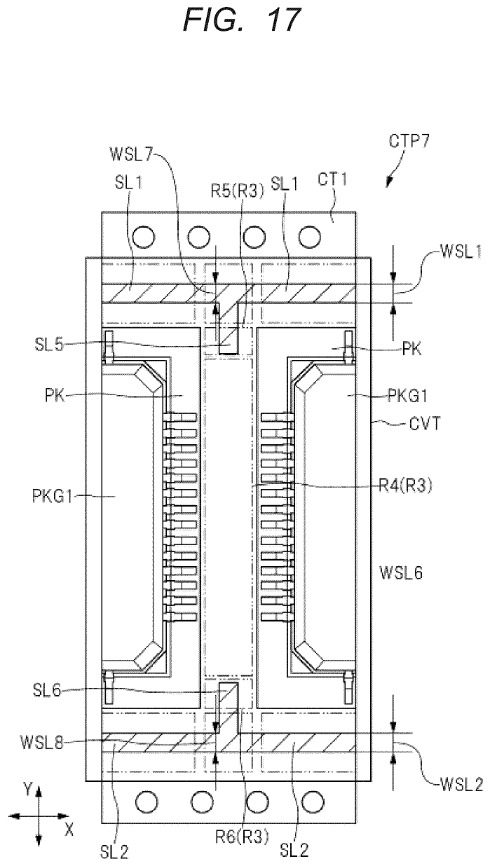

In the example shown in FIG. 8, a shape in plan view of each of the seal portion SL1, the seal portion SL2, the seal portion SL5 and the seal portion SL6 is comprised of a shape extended in the X-direction. As a modified example with respect to FIG. 8, for example, a circular shape in plan view may be used as the seal portion SL4 shown in FIG. 12. Forming a shape in plan view of each of the seal portion SL1, the seal portion SL2, the seal portion SL5 and the seal portion SL6 so as to extend along the X-direction as shown in FIG. 8 is preferred in comparison with the configuration of a carrier tape package CTP7 shown in FIG. 17 described below. That is, as described above, it is more difficult to align the carrier tape CT1 in the extending direction (X-direction shown in FIG. 12) than the alignment in the widthwise direction (Y-direction shown in FIG. 12) of the carrier tape CT1. Therefore, for example, when the seal portion SL5 and the seal portion SL6 shown in FIG. 8 are spotwise provided in a relatively small region like the seal portion SL4 shown in FIG. 12, depending on the degree of positional deviation of the seal portion SL5 and the seal portion SL6, there is a fear that the iron for thermocompression bonding the area R5 and the area R6 does not touch the area R5 and the area R6. This may be similar to the carrier tape package CTP2 shown in FIG. 10.

As shown in FIG. 8, when each of the seal portion SL5 and the seal portion SL6 has a planar shape extending in the X-direction, even if a part of the soldering iron for thermocompression bonding straddles the pocket PK, at least a part of the seal portion SL5 is formed in the area R5, and at least a part of the seal portion SL6 is highly likely to be formed in the area R6. Similarly, at least a portion of the seal SL1 and at least a portion of the seal SL2 are likely to be disposed next to the pocketed PK when each of the seal SL1 and the seal SL2 is in a planar configuration extending in the X-direction. Therefore, even if the positional deviation occurs, it is possible to prevent the semiconductor device PKG1 from being jumped out from the pocket PK as compared with the carrier tape package CTP2 shown in FIG. 10.

In the exemplary embodiment shown in FIG. 8, the seal portion SL7 disposed in the area R7 and the seal portion SL8 provided in the area R8 are further provided. The plurality of seal portions SL1 are connected to each other via the seal portion SL7. The plurality of seal portions SL2 are connected to each other via the seal portion SL8. If the connecting portion comprised of the seal portion SL1 and the seal portion SL7 is regarded as a single seal portion, it can be expressed as that the single seal portion is extending across the plurality of areas R1 and the plurality of areas R7. Similarly, when the connecting portion comprised of the seal portion SL2 and the seal portion SL8 is regarded as a single seal portion, it can be expressed as that the seal portion is extending across the plurality of areas R2 and the plurality of areas R8. Since the width of the seal portion SL1, the width of the seal portion SL2, the width of the seal portion SL7 and the width of the seal portion SL8 (Y-direction length) are the same as each other, the structure of these seal portion does not change even if the position deviation in the X-direction is generated temporarily.

### Modified Example

Next, a modified example regarding the shape and layout of the seal portion shown in FIGS. 8 and 9 will be described. In the following description, the comparative of the magnitude relationship of the width of each seal portion may be referred to, but the adhesive strength of the seal portion is proportional to the area of the seal portion when crimped at the same pressure and the same temperature. The magnitude relationship of the width of the seal portion described below can be applied by replacing the magnitude relationship of the adhesive strength of each seal portion.

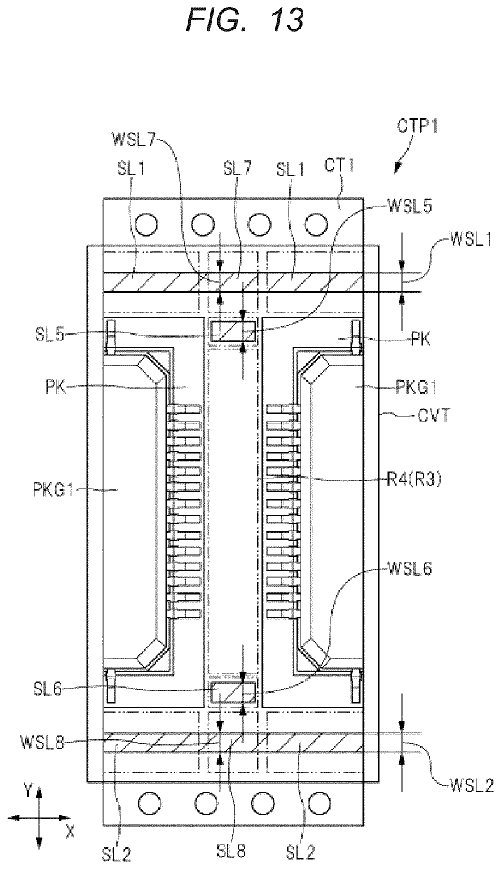

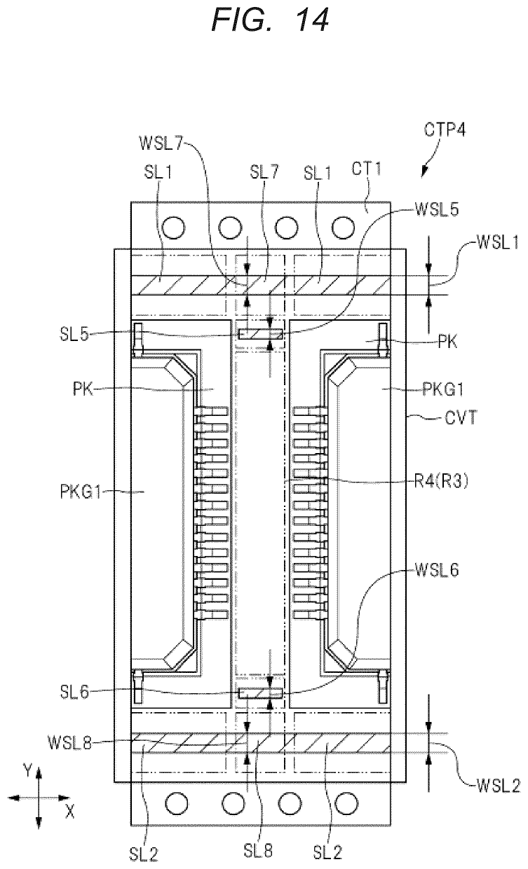

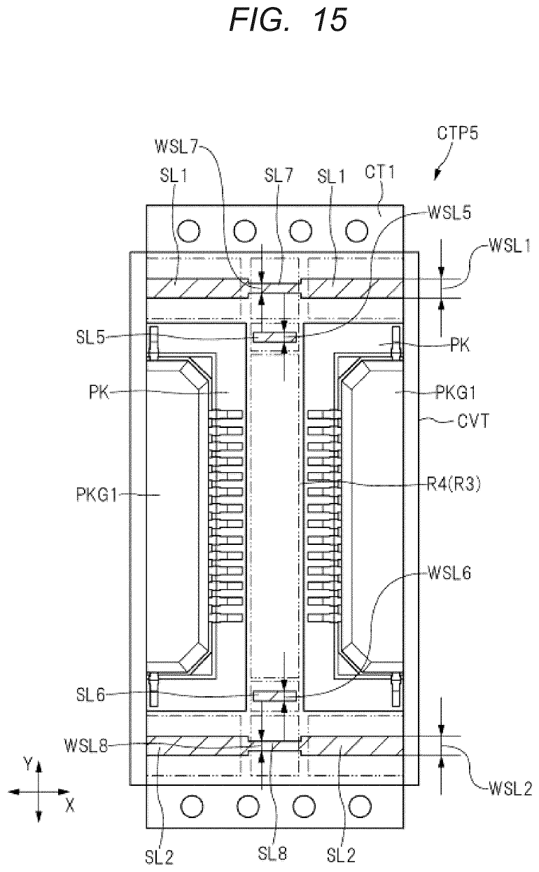

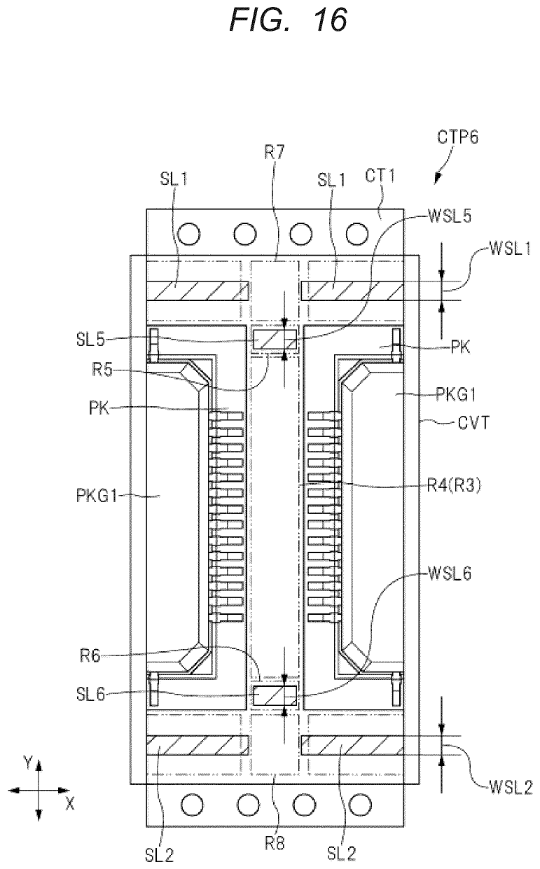

FIG. 13 is an enlarged plan view showing a periphery of a region between two pockets, which are adjacent to each other, of the plurality of pockets in the carrier tape package shown in FIG. 8. FIG. 14 is an enlarged plan view showing modified example with respect to FIG. 13. FIG. 15 is an enlarged plan view showing modified example with respect to FIG. 14. FIG. 16 is an enlarged plan view showing another modified example with respect to FIG. 13. In the carrier tape package CTP1 shown in FIG. 13, the width WSL1 of the seal portion SL1, the width SL2 of the seal portion SL2, the width WSL2 of the seal portion SL5, the width WSL5 of the seal portion SL6, the width WSL6 of the seal portion SL6, the width SL1 of the seal portion, and the width WSL2 of the seal portion SL1 are the same.

Here, it is preferable that the adhesive strength between the carrier tape CT1 and the cover tape CVT is constant in the X-direction in view of peel properties (easiness of peeling of the crimped part) between the carrier tape CT1 and the cover tape CVT. It should be noted that the “constant adhesive strength” may be set to the same level as long as no trouble occurs due to damages to the carrier tape package CTP1 when the carrier tape CT1 and the cover tape CVT are mechanically peeled off. Therefore, the present invention is not limited to the fact that the adhesive strengths are perfectly matched at all locations in the X-direction.

In the X-direction, in the area in which the seal portion SL5 and the seal portion SL6 are disposed, the adhesive strength of the seal portion SL5, the adhesive strength of the seal portion SL6, the adhesive strength of the seal portion SL7 and the adhesive strength of the seal portion SL8 are added together. Thus, the adhesive strength is higher than the adhesive strength in the area in which only the seal portion SL1 and the seal portion SL2 are disposed.

Therefore, in the carrier tape package (semiconductor device packaging body) CTP4 shown in FIG. 14, the width WSL5 of the seal portion SL5 is narrower than each of the width WSL1 of the seal portion SL1 and the width WSL2 of the seal portion SL2. Further, the width WSL6 of the seal portion SL6 is narrower than each of the width WSL1 of the seal portion SL1 and the width WSL2 of the seal portion SL2. In the step of thermocompression bonding, the adhesive strength of the seal portion in the Y-direction is proportional to the width of the seal portion when the thermocompression bonding is performed at the same pressure and the same temperature. Therefore, in the carrier tape package CTP4 shown in FIG. 14, as compared with the carrier tape package CTP1 shown in FIG. 13, it is possible to reduce the difference between the adhesive strength of the area in which the seal portion SL5 and the seal portion SL6 are disposed and the adhesive strength of the area in which the seal portion SL1 and the seal portion SL2 are disposed. Consequently, the carrier tape package CTP4 has a higher peel property between the carrier tape CT1 and the cover tape CVT than the carrier tape package CTP1.

Further, in the carrier tape package (the semiconductor device packaging body) CTP5 shown in FIG. 15, in addition to the configuration shown in FIG. 14, the width WSL7 of the seal portion SL7 is narrower than each of the width WSL1 of the seal portion SL1 and the width WSL2 of the seal portion SL2. Further, the width WSL8 of the seal portion SL8 is narrower than each of the width WSL1 of the seal portion SL1 and the width WSL2 of the seal portion SL2. In the embodiment shown in FIG. 15, the sum of the width WSL7 of the seal portion SL7 and the width WSL5 of the seal portion SL5 is equal to the value of the width WSL1 of the seal portion SL1. Similarly, the sum of the width WSL8 of the seal portion SL8 and the width WSL6 of the seal portion SL6 is equal to the value of the width WSL2 of the seal portion SL2.

If attention is paid to the point that the resistive force when the cover tape CVT and the carrier tape CT1 are peeled off is proportional to the width of each seal portion in the Y-direction, the carrier tape package CTP5 shown in FIG. 15 can further reduce the difference between the adhesive strength of the area where the seal portion SL5 and the seal portion SL6 are disposed and the adhesive strength of the area where the seal portion SL1 and the seal portion SL2 are disposed, as compared with the carrier tape package CTP4 shown in FIG. 14. In the carrier tape package CTP5, the difference between the adhesive strength of the area where the seal portion SL5 and the seal portion SL6 are disposed and the adhesive strength of the area where the seal portion SL1 and the seal portion SL2 are disposed can be regarded as substantially zero.

The carrier tape package (semiconductor device packaging body) CTP6 shown in FIG. 16 is different from the carrier tape package CTP1 shown in FIG. 13, the carrier tape package CTP4 shown in FIG. 14, and the carrier tape package CTP5 shown in FIG. 15 in that the seal portion SL7 and the seal portion SL8 shown in FIGS. 13 to 15 are not formed. Specifically, in the embodiment shown in FIG. 16, the plurality of seal portions SL1 arranged in the X-direction are spaced apart from each other via the area R7. Further, the plurality of seal portions SL2 arranged in the X-direction are spaced apart from each other via the area R8. In other words, the plurality of seal portions SL1 are divided by the area R7, and the plurality of seal portions SL2 are divided by the area R8.

The area R7 is an area disposed next to the area R5 in the Y-direction. The area R8 is an area disposed next to the area R6 in the Y-direction. Therefore, since the seal portion is not disposed in the area R7 and the area R8 (in other words, in the area R7 and the area R8, the carrier tape CT1 and the cover tape CVT are not thermally compression-bonded), it is possible to suppress an increase in the adhesive strength in the are in which the seal portion SL5 and the seal portion SL6 are disposed.

In the carrier tape package CTP6 shown in FIG. 16, the width WSL1 of the seal portion SL1, the width WSL2 of the seal portion SL2, the width WSL5 of the seal portion SL5, and the width WSL6 of the seal portion SL6 are the same as each other. In this case, the difference between the adhesive strength of the area in which the seal portion SL5 and the seal portion SL6 are disposed and the adhesive strength of the area in which the seal portion SL1 and the seal portion SL2 are disposed can be regarded as substantially zero.

As another modified example to FIG. 13, the seal portion SL5 and the seal portion SL6 extending in the Y-direction may be formed as in the carrier tape package (the semiconductor device packaging body) CTP7 shown in FIG. 17. FIG. 17 is an enlarged plan view showing another modified example with respect to FIG. 13. The carrier tape package CTP7 shown in FIG. 17 is different from the carrier tape package CTP shown in FIG. 13 in that the seal portion SL5 and the seal portion SL6 form a planar shape extending in the Y-direction. Specifically, each of the seal portion SL1 and the seal portion SL2 has a planar configuration extending in the X-direction. On the other hand, each of the seal portion SL5 and the seal portion SL6 has a planar configuration extending in the Y-direction intersecting the X-direction (perpendicular in FIG. 17).

In the carrier tape package CTP7, since the carrier tape CT1 and the cover tape CVT are thermocompression bonded to each other in each of the area R5 and the area R6, the phenomena in which semiconductor device PKG1 pops out from the pocket PK described with reference to FIG. 11 can be suppressed. Further, in the area R4, since the carrier tape CT1 and the cover tape CVT are not thermocompression bonded, even if a displacement of the sealing position occurs in the X-direction, semiconductor device PKG1 can be prevented from being damaged due to the displacement.

Although the invention made by the present inventor has been specifically described based on the embodiment, the present invention is not limited to the above embodiment, and it is needless to say that various modifications can be made without departing from the gist thereof.

What is claimed is:

1. A method of manufacturing a semiconductor device comprising:
(a) obtaining a plurality of semiconductor devices;
(b) preparing a carrier tape and a cover tape, the carrier tape having a plurality of pockets arranged in a first direction;
(c) accommodating the plurality of semiconductor devices in the plurality of pockets, respectively; and
(d) after the (c), attaching the cover tape to the carrier tape so as to cover the plurality of semiconductor devices respectively accommodated in the plurality of pockets,
wherein each of the plurality of semiconductor devices includes:
a semiconductor chip;
a plurality of leads arranged around the semiconductor chip in plan view; and
a sealing body sealing an inner lead portion of each of the plurality of leads and the semiconductor chip,
wherein the plurality of leads includes:
a first lead group arranged along a first side of the sealing body; and
a second lead group arranged along a second side of the sealing body, the second side being opposite the first side,
wherein the carrier tape prepared in the (b) includes:
a first long side extending in the first direction;
a second long side extending in the first direction and located on an opposite side of the first long side;
a first area located between the plurality of pockets and the first long side;
a second area located between the plurality of pockets and the second long side; and
a third area located between a first pocket of the plurality of pockets and a second pocket of the plurality of pockets, the first pocket and the second pocket being adjacent to each other,
wherein each of the plurality of pockets prepared in the (b) includes:
a sealing body accommodating portion for accommodating the sealing body;
a first lead accommodating portion extended along the first long side and for accommodating the first lead group; and
a second lead accommodating portion extended along the second long side and for accommodating the second lead group,
wherein the third area includes:
a fourth area located between the sealing body accommodating portion of the first pocket and the sealing body accommodating portion of the second pocket;
a fifth area located between the first lead accommodating portion of the first pocket and the first lead accommodating portion of the second pocket; and
a sixth area located between the second lead accommodating portion of the first pocket and the second lead accommodating portion of the second pocket, and
wherein, in the (d), the carrier tape and the cover tape are thermocompression bonded to each other at each of the first area, the second area, the fifth area and the sixth area without thermocompression bonding to each other at the fourth area.

2. The method according to claim 1,
wherein a portion in which the carrier tape and the cover tape are thermocompression bonded to each other in the (d) includes:
a first seal portion provided in the first area;
a second seal portion provided in the second area;
a fifth seal portion provided in the fifth area; and
a sixth seal portion provided in the sixth area, and
wherein a shape in plan view of each of the first seal portion, the second seal portion, the fifth seal portion and the sixth seal portion is comprised of a shape extended in the first direction.

3. The method according to claim 2,
wherein a width of the fifth seal portion is narrower than a width of each of the first seal portion and the second seal portion, and
wherein a width of the sixth seal portion is narrower than the width of each of the first seal portion and the second seal portion.

4. The method according to claim 3,
wherein the carrier tape includes:
a seventh area arranged in the first direction, located next to the first area, and located next to the fifth area in a second direction intersecting the first direction; and
an eighth area arranged in the first direction, located next to the second area, and located next to the sixth area in the second direction, and
wherein the portion in which the carrier tape and the cover tape are thermocompression bonded to each other in the (d) includes:
a seventh seal portion provided in the seventh area and extended in the first direction so as to connect a first portion of the first seal portion, which is located between the first pocket and the first long side, and a second portion of the first seal portion, which is located between the second pocket and the first long side, with each other; and
an eighth seal portion provided in the eighth area and extended in the first direction so as to connect a first portion of the second seal portion, which is located between the first pocket and the second long side, and a second portion of the second seal portion, which is located between the second pocket and the second long side, with each other.

5. The method according to claim 4,
wherein a width of the seventh seal portion is narrower than the width of each of the first seal portion and the second seal portion, and
wherein a width of the eighth seal portion is narrower than the width of each of the first seal portion and the second seal portion.

6. The method according to claim 2,
wherein the carrier tape includes:
a seventh area arranged in the first direction, located next to the first area, and located next to the fifth area in a second direction intersecting the first direction; and
an eighth area arranged in the first direction, located next to the second area, and located next to the sixth area in the second direction, and
wherein a first portion of the first seal portion, which is located between the first pocket and the first long side, and a second portion of the first seal portion, which is located between the second pocket and the first long side, are spaced apart from each other via the seventh area, and
wherein a first portion of the second seal portion, which is located between the first pocket and the second long side, and a second portion of the second seal portion, which is located between the second pocket and the second long side, are spaced apart from each other via the eighth area.

7. The method according to claim 6, wherein a width of the first seal portion, a width of the second seal portion, a width of the fifth seal portion and the sixth seal portion are the same as each other.

8. The method according to claim 1,
wherein a portion in which the carrier tape and the cover tape are thermocompression bonded to each other in the (d) includes:
a first seal portion provided in the first area;
a second seal portion provided in the second area;
a fifth seal portion provided in the fifth area; and
a sixth seal portion provided in the sixth area,
wherein a shape in plan view of each of the first seal portion and the second seal portion is comprised of a shape extended in the first direction, and
wherein a shape in plan view of each of the fifth seal portion and the sixth seal portion is comprised of a shape extended in a second direction intersecting the first direction.

9. The method according to claim 1,
wherein the plurality of leads includes:
a third lead group arranged along a third side of the sealing body, the third side being extended in a direction intersecting each of the first side and the second side; and
a fourth lead group arranged along a fourth side of the sealing body, the fourth side being opposite the first long side, and
wherein each of the plurality of pockets prepared in the (b) includes:
a third lead accommodating portion for accommodating the third lead group; and
a fourth lead accommodating portion for accommodating the fourth lead group.

10. A semiconductor device packaging body comprising:
a carrier tape having a plurality of pockets arranged in a first direction;
a plurality of semiconductor devices accommodated in the plurality of pockets, respectively; and
a cover tape attached to the carrier tape so as to cover the plurality of semiconductor devices respectively accommodated in the plurality of pockets,
wherein each of the plurality of semiconductor devices includes:
a semiconductor chip;
a plurality of leads arranged around the semiconductor chip in plan view; and
a sealing body sealing an inner lead portion of each of the plurality of leads and the semiconductor chip, wherein the plurality of leads includes:
a first lead group arranged along a first side of the sealing body; and
a second lead group arranged along a second side of the sealing body, the second side being opposite the first side,
wherein the carrier tape includes:
a first long side extending in the first direction;
a second long side extending in the first direction and located on an opposite side of the first long side;
a first area located between the plurality of pockets and the first long side;
a second area located between the plurality of pockets and the second long side; and
a third area located between a first pocket of the plurality of pockets and a second pocket of the plurality of pockets, the first pocket and the second pocket being adjacent to each other,
wherein each of the plurality of pockets includes:
a sealing body accommodating portion for accommodating the sealing body;
a first lead accommodating portion extended along the first long side and for accommodating the first lead group; and
a second lead accommodating portion extended along the second long side and for accommodating the second lead group,
wherein the third area includes:
a fourth area located between the sealing body accommodating portion of the first pocket and the sealing body accommodating portion of the second pocket;
a fifth area located between the first lead accommodating portion of the first pocket and the first lead accommodating portion of the second pocket; and
a sixth area located between the second lead accommodating portion of the first pocket and the second lead accommodating portion of the second pocket, and
wherein each of the first area, the second area, the fifth area and the sixth area has a seal portion at where the carrier tape and the cover tape are thermocompression bonded to each other, while the fourth area has no seal portion at where the carrier tape and the cover tape are thermocompression bonded to each other.

11. The semiconductor device packaging body according to claim 10,
wherein the seal portion at where the carrier tape and the cover tape are thermocompression bonded to each other includes:
a first seal portion situated in the first area;
a second seal portion situated in the second area;
a fifth seal portion situated in the fifth area; and
a sixth seal portion situated in the sixth area, and
wherein a shape in plan view of each of the first seal portion, the second seal portion, the fifth seal portion and the sixth seal portion is comprised of a shape extended in the first direction.

12. The semiconductor device packaging body according to claim 11,
wherein a width of the fifth seal portion is narrower than a width of each of the first seal portion and the second seal portion, and
wherein a width of the sixth seal portion is narrower than the width of each of the first seal portion and the second seal portion.

13. The semiconductor device packaging body according to claim 10,
wherein the plurality of leads includes:
a third lead group arranged along a third side of the sealing body, the third side being extended in a direction intersecting each of the first side and the second side; and
a fourth lead group arranged along a fourth side of the sealing body, the fourth side being opposite the first long side, and
wherein each of the plurality of pockets prepared in the (b) includes:
a third lead accommodating portion for accommodating the third lead group; and
a fourth lead accommodating portion for accommodating the fourth lead group.
